(19) United States
(12) Patent Application Publication
(10) Pub. No.: US 2017/0243880 A1
(43) Pub. Date: Aug. 24, 2017

(54) SEMICONDUCTOR MANUFACTURING DEVICE AND METHOD OF MANUFACTURING A SEMICONDUCTOR DEVICE

(71) Applicant: Kabushiki Kaisha Toshiba, Minato-ku (JP)

(72) Inventor: Yuya MATSUDA, Mie (JP)

(73) Assignee: Kabushiki Kaisha Toshiba, Minato-ku (JP)

(21) Appl. No.: 15/212,495

(22) Filed: Jul. 18, 2016

(30) Foreign Application Priority Data
Feb. 18, 2016 (JP) 2016-028964

(51) Int. Cl. H01L 27/115; H01L 21/28; H01L 21/311; H01L 21/66; H01L 21/683; H01L 21/67

(52) U.S. Cl. CPC H01L 27/11582; H01L 21/6831; H01L 21/67103; H01L 21/67253; H01L 21/31144; H01L 21/31116; H01L 21/67069; H01L 22/26; H01L 21/28282

(57) ABSTRACT

According to one embodiment, when a wafer is placed on a base stand and a first frequency voltage is applied to the base stand, the potential of the wafer is measured, and the first frequency voltage is applied in a pulsed manner to the base stand and a base stand voltage is applied to the base stand, and the amplitude of the base stand voltage is controlled based on the potential of the wafer in synchronization with the timing for a pulse waveform cf the first frequency voltage.

### CROSS-REFERENCE TO RELATED APPLICATIONS

This application is based upon and claims the benefit of priority front Japanese Patent Application No. 2016-28964, filed on Feb. 18, 2016; the entire contents of which are incorporated herein by

### FIELD

Embodiments described herein relate generally to a semiconductor manufacturing device and a method of manufacturing a semiconductor device.

### BACKGROUND

In a plasma etching device, bias control power may be made higher with increase in aspect ratio or the like.

### BRIEF DESCRIPTION OF THE DRAWINGS

FIG. 1 is a schematic cross-sectional view of a semiconductor manufacturing device according to a first embodiment;

FIG. 2A is a diagram illustrating a voltage waveform of a source power supply illustrated in FIG. 1, FIG. 2B is a diagram illustrating a voltage waveform of a bias control power supply illustrated in FIG. 1, FIG. 2C is a diagram illustrating a voltage waveform applied to the wafer illustrated in FIG. 1, and FIG. 2D is a diagram illustrating a voltage waveform of a base stand power supply illustrated in FIG. 1;

FIG. 3 is a flowchart of a control method of a base stand voltage in a semiconductor manufacturing device according to a second embodiment;

FIG. 4 is a flowchart of a control method of a base stand voltage in a semiconductor manufacturing device according to a third embodiment;

FIGS. 5A to 5C are cross-sectional views describing a manufacturing method of a semiconductor device according to a fourth embodiment; and

FIGS. 6A to 6C are cross-sectional views describing the manufacturing method of a semiconductor device according to the fourth embodiment, and Fig. ID is an enlarged cross-sectional view of an El portion illustrated in FIG. 6C.

### DETAILED DESCRIPTION

In general, according to one embodiment, when a wafer is placed on a base stand and a first frequency voltage is applied to the base stand, the potential of the wafer is measured, and the first frequency voltage is applied in a pulsed manner to the base stand and a base stand voltage is applied to the base stand, and the amplitude of the base stand voltage is controlled based on the potential of the wafer in synchronization with the timing for a pulse waveform of the first frequency voltage.

Exemplary embodiments of a semiconductor manufacturing device will be explained below in detail with reference to the accompanying drawings. The present invention is not limited to the following embodiments.

### First Embodiment

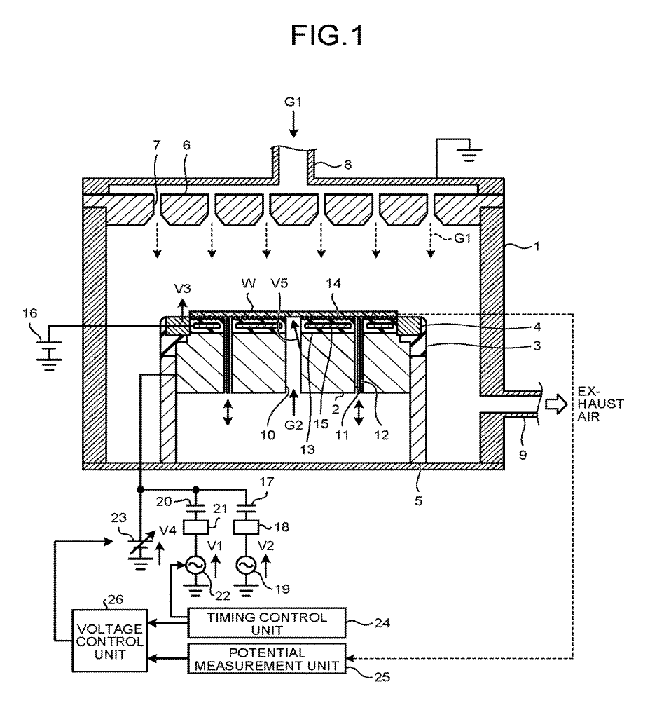

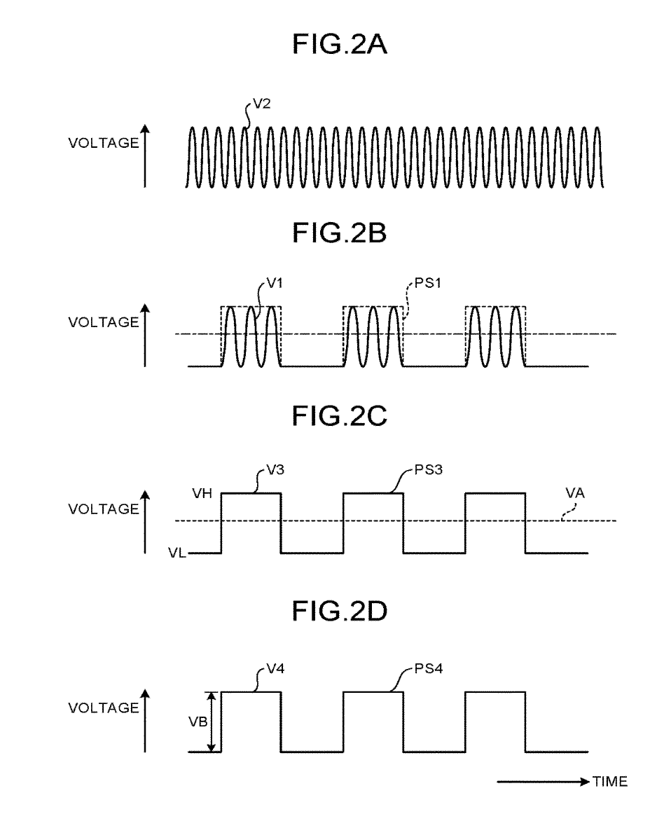

FIG. 1 is a schematic cross-sectional view of a semiconductor manufacturing device according to a first embodiment. FIG. 2A is a diagram illustrating a voltage waveform of a source power supply illustrated in FIG. 1, FIG. 2B is a diagram illustrating a voltage waveform of a bias control power supply illustrated in FIG. 1, FIG. 2C is a diagram illustrating a voltage waveform applied to the wafer illustrated in FIG. 1, and FIG. 2D is a diagram illustrating a voltage waveform of a base stand power supply illustrated in FIG. 1. FIG. 1 illustrates a capacitance-coupled (parallel plate-type) plasma etching device as an example.

Referring to FIG. 1, the etching device includes a chamber 1 for storing a wafer W. A base stand 2 for holding the wafer W is provided in the chamber 1. The chamber 1 and the base stand 2 can be formed from a conductive body of Al or the like. The chamber 1 can be grounded. The base stand 2 is held in the chamber 1 by a support body 5. An insulation ring 3 is provided on the outer periphery of the base stand 2. A focus ring 4 is embedded in a boundary between the base stand 2 and the insulation ring 3 along the outer periphery of the wafer W. The focus ring 4 can prevent deflection of an electric field at the peripheral edge portion of the wafer W.

A shower head 6 is installed at the upper part of the interior of the chamber 1. The shower head 6 can jet a gas G1 in a vertical direction from above the wafer W toward the wafer surface. The shower head 6 can have injection holes 7 to jet the gas G1. A pipe 8 is provided above the shower head 6 to supply the gas G1 to the shower head 6. The gas G1 can advance a plasma etching process within the chamber 1. The shower head 6 can be used as an upper electrode at the time of generation of plasma. The base stand 2 can be used as a lower electrode at the time of generation of plasma. An exhaust pipe 9 is provided at the lower part of the chamber 1.

An electrostatic chuck 13 is provided on the base stand 2 to fix the wafer W. A chuck electrode 15 is embedded into the electrostatic chuck 13. The chuck electrode 15 is connected to a chuck power supply 16. The chuck electrode 15 can generate electrostatic force to attract the wafer W. The electrostatic chuck 13 has a corrugated surface 14 on the front side. The corrugated surface 14 may be an embossed surface.

The base stand 2 and the electrostatic chuck 13 have through holes 10 and 11. The through hole 10 can send a cooling agent G2 to the back surface of the wafer W. The cooling agent G2 may be a He gas, for example. The cooling agent G2 sent to the back surface of the wafer W can enter into the corrugated surface 14. The cooling agent G2 sent to the back surface of the wafer W can spread over the entire back surface of the wafer W via the corrugated surface 14. A pin 12 is provided in the through hole 11. The bin 12 is vertically movable. The pin 12 is vertically moved to ascend and descend the wafer W during transfer of the wafer W.

The etching device is also provided with a source power supply 19, a bias control power supply 22, and a base stand power supply 23. The bias control power supply 22 can apply a first frequency voltage V1 in a pulsed manner to the base stand 2. The source power supply 19 can apply continuously a second frequency voltage V2 to the base stand 2. The second frequency can be higher than the first frequency. For example, the first frequency can be set to 13.56 MHz or lower, and the second frequency to 40 MHz or more. The second frequency voltage V2 can be used to generate plasma in the chamber 1. The first frequency voltage V1 can be used as a bias voltage to draw into the wafer W ions generated in the chamber 1. The base stand power supply 23 can apply a base stand voltage V4 to the base stand 2. The base stand voltage V4 can be used to cancel potential V3 of the wafer W.

The bias control power supply 22 is connected to the base stand 2 via a blocking capacitor 20 and a matching box 21 in sequence. The source power supply 19 is connected to the base stand 2 via a blocking capacitor 17 and a matching box 18 in sequence. The base stand power supply 23 is connected to the base stand 2. The blocking capacitors 17 and 20 can dampen damage due to ion collision at the time of etching. The matching box 18 can make impedance matching with a load of the source power supply 19. The matching box 21 can make impedance matching with a load of the bias control power supply 22.

The etching device also includes a timing control unit 24, a potential measurement unit 25, and a voltage control unit 26. The timing control unit 24 can control the timing of a pulse waveform of the first frequency voltage V1. The timing control unit 24 can control the on/off timing of the first frequency voltage V1 to control the timing of pulse waveform of the first frequency voltage V1. The potential measurement unit 25 can measure the potential V3 of the wafer W. The voltage control unit 26 can control the amplitude of the base stand voltage V4 based on the potential V3 of the wafer W in synchronisation with the timing of the pulse waveform of the first frequency voltage V1.

When the wafer P is transferred into the chamber 1, the pin 12 protrudes above the electrostatic chuck 13. Then, the pin 12 descends with the wafer W placed on the pin 12, and the wafer P is placed on the electrostatic chuck 13. The wafer P is attracted to the electrostatic chuck 13 and fixed on the electrostatic chuck 13.

Then, the cooling agent G2 is sent to the back surface of the wafer W via the through hole 10 and spread over the entire back surface of the wafer W via the corrugated surface 14 to cool the wafer W. The shower head jets the gas G1 while air is evacuated from the chamber 1 via the exhaust pipe 9. As illustrated in FIG. 2A, when the source power supply 19 supplies the second frequency voltage V2 to the base stand 2, the gas G1 becomes ionized to generate plasma on the wafer W. At that time, as illustrated in FIG. 2B, the bias control power supply 22 applies the first frequency voltage V1 to the base stand 2 in a pulsed manner to draw ions generated in the chamber 1 into the wafer W. The timing control unit 24 can control the on/off timing of the first frequency voltage V1 to control a pulse form PS1 of the first frequency voltage V1. At that time, the base stand power supply 23 applies the base stand voltage V4 to the base stand 2. Then, an etching process is performed by the ions generated on the wafer W attacking the wafer J and reacting on the wafer W.

While the wafer W is placed on the base stand 2 to which the first frequency voltage V1 is applied, the potential measurement unit 25 measures the potential V3 of the wafer W. When the first frequency voltage V1 is applied in a pulsed manner to the base stand 2, the potential V3 of the wafer W also becomes pulsed and has a pulse waveform PS3 identical to the pulse waveform PS1 as illustrated in FIG. 20. Accordingly, the potential V3 of the wafer W alternates between a high potential VH and a low potential VL. At that time, the potential measurement unit 25 may measure a DC voltage VA of the wafer W as the potential V3 of the wafer W. The potential measurement unit 25 may correct the DC voltage VA of the wafer W based on a duty of the pulse waveform PS1. The voltage control unit 26 controls an amplitude VB of the base stand voltage V4 based on the potential V3 of the wafer W in synchronization with the timing of the pulse waveform PS1 of the first frequency voltage V1 as illustrated in FIG. 2D. The base stand voltage V4 may have a pulse waveform PS4 identical to the pulse waveform PS1. The voltage control unit 26 can control the amplitude VP of the base stand voltage V4 such that a potential difference V5 between the base stand 2 and the wafer W comes close to zero.

Accordingly, the first frequency voltage V1 is applied in a pulsed manner to the base stand 2, and it is possible to prevent application of a high voltage between the base stand 2 and the wafer W even when the potential V3 of the wafer W alternates between the high voltage VH and the low voltage VL. This avoids the occurrence of electric discharge from the back surface of the wafer W above the through holes 10 and 11.

The voltage control unit 26 may not necessarily control the amplitude VP of the base stand voltage V4 such that the potential difference V5 between the base stand and the wafer N becomes equal to zero but may control the amplitude VB of the base stand voltage V4 such that the potential difference V5 between the base stand 2 and the wafer W falls under a range in which no electric discharge occurs from the back surface of the wafer W above the through holes 10 and 11.

In the embodiment, the semiconductor manufacturing device is a capacity-coupled plasma etching device as an example. Alternatively, the semiconductor manufacturing device may be an inductively coupled plasma etching device or a microwave ECR (electron cyclotron resonance) plasma etching device.

### Second Embodiment

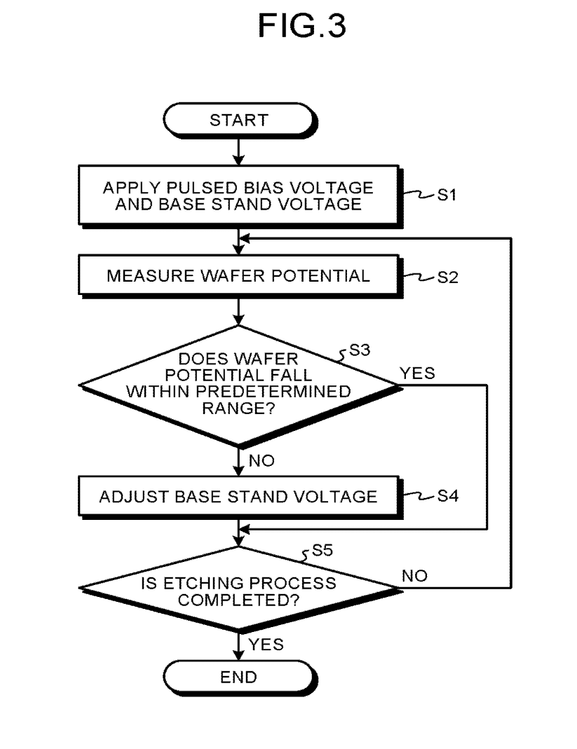

FIG. 3 is a flowchart of a control method of a base stand voltage in a semiconductor manufacturing device according to a second embodiment.

Referring to FIG. 3, when the wafer W is transferred onto the base stand 2, the bias control power supply 22 applies a pulsed bias voltage (the first frequency voltage V1) to the base stand 2, and the base stand power supply 23 applies the pulsed base stand voltage V4 to the base stand (S1).

Next, the potential measurement unit 25 measures the potential V3 of the wafer W (S2). Then, the potential measurement unit 25 determines whether the potential V3 of the wafer W falls within a predetermined range (S3). When the potential V3 of the wafer W does not fall within the predetermined range, the voltage control unit 26 adjusts the amplitude VB of the base stand voltage V4 (34). When the potential V3 of the wafer W falls within the predetermined range, the voltage control unit 26 skips the adjustment of the amplitude VB of the base stand voltage V4. The predetermined range can he set as a range in which no electric discharge occurs from the back surface of the wafer W above the through holes 10 and 11, for example. A margin nay be included in the range in which no electric discharge occurs from the back surface of the wafer W above the through holes 10 and 11.

Next, it is determined whether the etching process is completed (S5). When the etching process is not yet completed, the process returns to S2 to repeat steps S2 to S5 until completion of the etching process.

Accordingly, even when the potential V3 of the wafer W varies in the course of the etching process, the amplitude VB of the base stand voltage V4 can follow the fluctuations in the potential V3 of the wafer W to prevent the occurrence of electric discharge from the back surface of the wafer W above the through holes 10 and 11.

### Third Embodiment

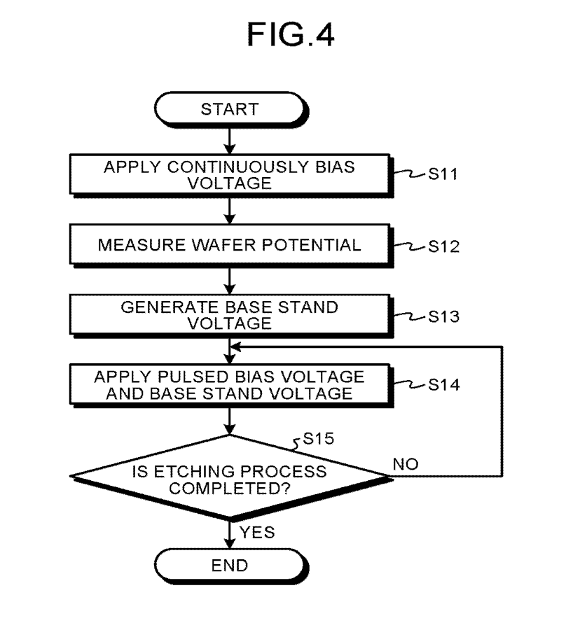

FIG. 4 is a flowchart of a control method of a base stand voltage in a semiconductor manufacturing device according to a third embodiment.

Referring to FIG. 4, when the wafer W is transferred onto the base stand 2, the bias control power supply 22 applies continuously a bias voltage (the first frequency voltage V1) to the base stand 2 (S11).

Next, the potential measurement unit 25 measures the potential V3 of the wafer N (S12). By applying continuously the bias voltage to the base stand 2, the measured value of the potential V3 of the wafer W illustrated in FIG. 2C can be equalized to the DC voltage VA. Then, the voltage control unit 26 sets the amplitude VB of the base stand voltage V4 based on the potential V3 of the wafer (S13).

Next, the bias control power supply 22 applies a pulsed bias voltage (the first frequency voltage V1) to the base stand 2, and the base stand power supply 23 applies the pulsed base stand voltage V4 to the base stand 2 (S14).

Next, it is determined whether the etching process is completed (S15). When the etching process is not yet completed, the process returns to S14 to repeat S14 to S15 until the completion of the etching process.

By measuring the potential V3 of the wafer W while applying continuously the bias voltage to the base stand 2, the measured value of the potential V3 of the wafer W can be equalized to the DC voltage VA. Accordingly, the measurement accuracy of the potential V3 of the wafer W can be improved as compared to the case of measuring the potential V3 of the wafer W while applying the pulsed bias voltage to the base stand 2.

### Fourth Embodiment

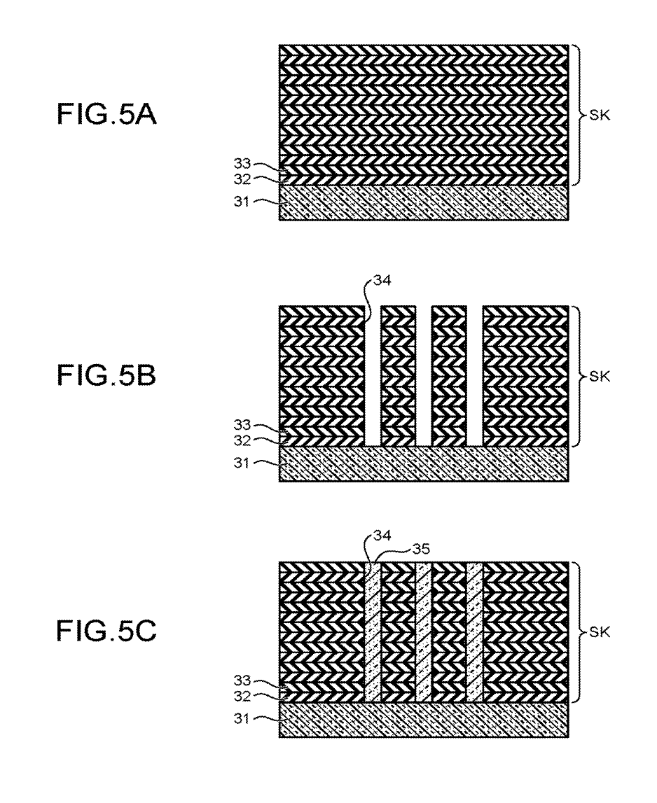

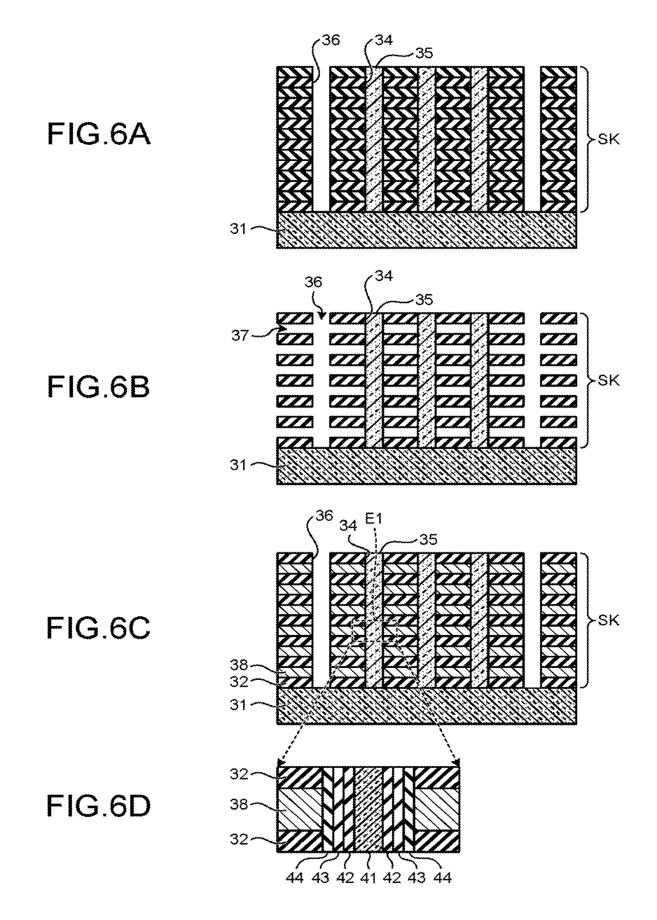

FIGS. 5A to 5C and 6A to 6C are cross-sectional views describing a manufacturing method of a semiconductor device according to a fourth embodiment, and FIG. 6D is an enlarged cross-sectional view of an El portion illustrated in FIG. 6C.

Referring to FIG. 5A, the wafer W has a base layer 31. The base layer 31 may be the wafer W itself or an insulation layer or a semiconductor layer. The base layer 31 may have an integrated circuit, a wiring, and the like formed thereon.

A stacked body SK is formed on the base layer 31. The stacked body SK has insulation layers 32 and 33 different in material stacked alternately by a method or CVD. For example, the insulation layer 32 may be a silicon oxide film, and the insulation layer 33 may be a silicon nitride film. The thickness of the insulation layers 32 and 33 can be set to several tens nm, for example. The number of the insulation layers 32 and 33 can be set to several tens to several hundreds, for example.

As illustrated in FIG. 5B, memory holes 34 are formed in the stacked body SK by the use of a photolithography technique or a dry etching technique. The diameter of the memory holes 34 can be set to several tens nm, for example. The memory holes 34 can be formed by the etching device illustrated in FIG. 1. The use of the etching device illustrated in FIG. 1 makes it possible to improve the dimensional accuracy and plane uniformity of the memory holes 34 in correspondence with increase in the aspect ratio of the memory holes 34.

Next, as illustrated in FIG. 5C, columnar bodies 35 are embedded into the memory holes 34 by a method such as CVD. The columnar bodies 35 can be provided with memory films storing data along the inner peripheries of the memory holes 34.

Next, as illustrated in FIG. 6A, slits 36 are formed in the stacked body SK by a lithography technique or a dry etching technique. The slits 36 can be formed by the use of the etching device illustrated in FIG. 1. The use of the etching device illustrated in FIG. 1 makes it possible to improve the dimensional accuracy and plane uniformity of the slits 36 in correspondence with increase in the aspect ratio of the slits 36.

Next, as illustrated in FIG. 65, the insulation layers 33 are selectively etched by a method such as wet etching to form gaps 37 between the insulation layers 32.

Next, as illustrated in FIG. 6C, conductive films 38 are embedded into the gaps 37 by a method such as CVD. The material for the conductive films 38 can be tungsten or polysilicon, for example. The top and bottom conductive films 38 can be used as select gate lines in an NAND flash memory. The intermediate conductive films 38 can be used as word lines in the NAND flash memory.

As illustrated in FIG. 6D, a columnar semiconductor 41 is formed in the center of the columnar body 35. A tunnel insulation film 42 is formed between the inner surface of the memory hole 34 and the columnar semiconductor 41. A charge trap layer 43 is formed between the inner surface of the memory hole 34 and the tunnel insulation film 42. A block insulation film 44 is formed between the inner surface of the memory hole 34 and the charge trap layer 43. The charge trap layer 43 can be used as a memory film storing data. The columnar semiconductor 41 can be a semiconductor such as Si, for example. The tunnel insulation film 42 and the block insulation film 44 can be silicon oxide films, for example. The charge trap layer 43 can be a silicon nitride film or an ONO film (three-layer structure of silicon oxide film/silicon nitride film/silicon oxide film), for example. The configuration illustrated in FIG. 6D can be used as a memory cell in the NAND flash memory.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor manufacturing device comprising:
a chamber storing a wafer;
a base stand holding the wafer in the chamber;
a bias control power supply that applies a first frequency voltage in a pulsed manner to the base stand;
a base stand power supply that applies a base stand voltage to the base stand;
a voltage control unit that controls the amplitude of the base stand voltage based on the potential of the wafer; and
a timing control unit that controls a changing timing of the amplitude of the base stand voltage based on the timing of the pulse waveform of the first frequency voltage.

2. The semiconductor manufacturing device of claim 1, further comprising a source power supply that applies continuously to the base stand a second frequency voltage higher in frequency than the first frequency voltage.

3. The semiconductor manufacturing device of claim 1, further comprising an electrostatic chuck that is provided on the base stand to fix the wafer.

4. The semiconductor manufacturing device of claim 3, comprising a first hole that penetrates through the base stand and the electrostatic chuck to send a cooling agent to the back surface of the wafer.

5. The semiconductor manufacturing device of claim 3, comprising:
a second hole that penetrates through the base stand and the electrostatic chuck; and
a pin that is provided in the second hole to ascend and descend the wafer.

6. The semiconductor manufacturing device f claim 1, comprising a shower head that is provided above the base stand to jet a gas toward the base stand.

7. The semiconductor manufacturing device of claim 1, wherein the voltage control unit controls the amplitude of the base stand voltage such that the potential of the wafer falls within a predetermined range.

8. The semiconductor manufacturing device of claim 1, wherein the potential of the wafer is measured when the first frequency voltage is applied in a pulsed manner to the base stand.

9. The semiconductor manufacturing device of claim 8, wherein the voltage control unit controls the amplitude of the base stand voltage such that the amplitude of the base stand voltage follows fluctuations in the potential of the wafer.

10. The semiconductor manufacturing device of claim 1, wherein the potential of the wafer is measured when the first frequency voltage is continuously applied to the base stand before the first frequency voltage is applied in a pulsed manner to the base stand.

11. A manufacturing method of a semiconductor device comprising:
forming a film on a wafer;
forming a mask pattern with a first opening portion on the film; and
forming a second opening portion in the film by etching the film via the mask pattern, wherein
at the time of formation of the second opening portion,
a first frequency voltage is applied to a base stand in a pulsed manner and a base stand voltage is applied to the base stand when the wafer is placed on the base stand, and
an amplitude of the base stand voltage is controlled based on a potential of the wafer, and a changing timing of the amplitude of the base stand voltage is controlled based on a timing of a pulse waveform of the first frequency voltage.

12. The manufacturing method of a semiconductor device of claim 11, wherein the film is a columnar body in which a first insulation layer and a second insulation layer are alternately stacked on the wafer.

13. The manufacturing method of a semiconductor device of claim 11, further comprising:
embedding a columnar body with a memory film into the second opening portion;
forming a slit in the stacked body;
removing the second insulation layer by entering an etching agent into the stacked body via the slit; and
embedding a conductor into a gap from which the second insulation layer is removed, wherein
at the time of formation of the slit,
a first frequency voltage is applied to a base stand in a pulsed manner and a base stand voltage is applied to the base stand when the wafer is placed on the base stand, and
an amplitude of the base stand voltage is controlled based on a potential of the wafer, and a changing timing of the amplitude of the base stand voltage is controlled based on a timing of a pulse waveform of the first frequency voltage.

14. The manufacturing method of a semiconductor device of claim 11, wherein a second frequency voltage higher in frequency than the first frequency voltage is continuously applied to the base stand.

15. The manufacturing method of a semiconductor device of claim 11, wherein the wafer is fixed on the base stand via an electrostatic chuck.

16. The manufacturing method of a semiconductor device of claim 15, wherein a cooling agent is sent to the back surface of the wafer via a first hole penetrating through the base stand and the electrostatic chuck.

17. The manufacturing method of a semiconductor device of claim 15, wherein the wafer is ascended and descended via a pin provided in a second hole penetrating through the base stand and the electrostatic chuck.

18. The manufacturing method of a semiconductor device of claim 11, wherein an etching gas is jetted toward the base stand via a shower head provided above the base stand.

19. The manufacturing method of a semiconductor device of claim 11, wherein the potential of the wafer is measured when the first frequency voltage is applied in a pulsed manner to the base stand.

20. The manufacturing method of a semiconductor device of claim 11, wherein
the first frequency voltage is continuously applied to the base stand before the first frequency voltage is applied in a pulsed manner to the base stand,
the potential of the wafer is measured when the first frequency voltage is continuously applied to the base stand, and
the amplitude of the base stand voltage is controlled based on the potential of the wafer when the first frequency voltage is applied in a pulsed manner to the base stand.
